(19) United States
(12) Patent Application Publication
(10) Pub. No.: US 2008/0299313 A1
(43) Pub. Date: Dec. 4, 2008

(54) Film forming apparatus and film forming method

(75) Inventor: Takeshi Kijima, Matsumoto-shi (JP)

Correspondence Address: Edwards Angell Palmer & Dodge LLP, P.O. Box 55874, Boston, MA, 02205, US

(73) Assignee: Seiko Epson Corporation, Tokyo (JP)

(21) Appl. No.: 12/151,111

(22) Filed: May 2, 2008

(30) Foreign Application Priority Data
May 2, 2007 (JP) 2007-121516

(51) Int. Cl. C23C 16/06; C23C 16/54; C23C 16/38

(52) U.S. Cl. 427/255.33; 118/719; 427/255.28; 427/255.29; 427/255.31; 427/255.38

(57) ABSTRACT

A film forming apparatus that forms a film on an inner wall of a tubular body by a chemical vapor deposition method is provided. The film forming apparatus includes: a source material storage section; a process gas generation section that forms process gas containing source material supplied from the source material storage section; a film forming section that forms a film on an inner wall of the tubular body; a process gas supply tube that connects to the tubular body and supplies the process gas from the process gas generation section to the tubular body; and a process gas discharge tube that connects to the tubular body and discharges the process gas that has passed through the tubular body, wherein the film forming section includes a retaining section that holds the tubular body.

The entire disclosure of Japanese Patent Application No. 2007-121516, filed May 2,2007 is expressly incorporated by reference herein.

### BACKGROUND

1. Technical Field

The present invention relates to a film forming method and a film forming apparatus using, chemical vapor deposition (CVD).

2. Related Art

Quartz glass tubes are used as arc tubes of light emitting lamps that may be used for projectors or the like (for example, see JP-A-2005-309372). When quartz glass is exposed to high-temperatures, its glass state (amorphous) transforms to cristobalite (crystalline) state, in other words, devitrification in which transparent glass discolors in white occurs. In the case of quartz glass, devitrification normally occurs at 1150° C. or higher. However, for example, when an electrode material that is thermally evaporated adheres as an impurity to an inner surface of a quartz glass tube of a lamp, the temperature at which devitrification occurs (hereafter referred to as a “devitrification temperature”) may lower, and devitrification of quartz glass of the quartz glass tube may occur at a temperature below 1000° C. The lowered devitrification temperature may shorten the service life of the lamp.

The inventors of the present application described a technology for forming a ceramics film on an inner wall of a quart glass tube to solve the above-described problem in a Japanese laid-open patent application JP-A-2007-180138.

### SUMMARY

In accordance with an advantage of some aspects of the invention, a film forming apparatus and a film forming method for forming a film on an inner wall of a tubular body, such as, a glass tube can be provided.

A film forming apparatus in accordance with an embodiment of the invention pertains to a film forming apparatus that forms a film on an inner wall of a tubular body by a chemical vapor deposition method, the film forming apparatus including: a source material storage section; a process gas generation section that forms process gas containing source material supplied from the source material storage section; a film forming section that forms a film on an inner wall of the tubular body; a process gas supply tube that is connected to the tubular body and supplies the process gas from the process gas generation section to the tubular body; and a process gas discharge tube that is connected to the tubular body and discharges the process gas that has passed through the tubular body, wherein the film forming section includes a retaining section that holds the tubular body.

According to the film forming apparatus in accordance with the embodiment of the invention, a film is directly formed on the inner wall of the tubular body by a chemical vapor deposition method. Accordingly, because the tubular body has a smaller volume compared to that of a processing chamber of an ordinary CVD apparatus, and a reduction in the process gas temperature due to adiabatic expansion within the tubular body can be made substantially small, the temperature control becomes easy and an excellent film can be formed in a state with smaller energy required for heating.

In the film forming apparatus in accordance with an aspect of the invention, the film forming section may further include a heating section for heating the tubular body.

In the film forming apparatus in accordance with an aspect of the invention, the process gas generation section may include a plurality of gas chamber sections disposed at intervals, a plurality of through-flow pipes that connect the plurality of gas chamber sections, and a heating section that heats the plurality of gas chamber sections and the plurality of through-flow pipes.

In the film forming apparatus in accordance with an aspect of the invention, adjacent upper and lower sets of the plurality of through-flow pipes with respect to each of the gas chambers may not overlap each other in a plan view.

In the film forming apparatus in accordance with an aspect of the invention, the tubular body may be a glass tube for a lamp.

In the film forming apparatus in accordance with an aspect of the invention, the process gas supply tube may include a plurality of supply branch pipes, the process gas discharge pipe may include a plurality of discharge branch pipes, and the retaining section may connect the supply branch pipes and the discharge branch pipes, respectively.

A film forming method in accordance with an embodiment of the invention pertains to a film forming method that forms a film on an inner wall of a tubular body by a chemical vapor deposition method, the method including the steps of: setting a tubular body at a retaining section of the film forming apparatus, and connecting the tubular body to a process gas supply pipe and to a process gas discharge pipe; supplying at least source material gas to a process gas generation section; supplying the process gas from the process gas generation section to the tubular body through the process gas supply pipe; forming a film on an inner wall of the tubular body by a chemical vapor deposition method using the process gas; and discharging the process gas that has passed through the tubular body from the process gas discharge pipe.

The film forming method in accordance with an aspect of the invention may further include heating the tubular body by a heating section, and maintaining the tubular body at a film forming temperature.

In the film forming method in accordance with an aspect of the invention, the process gas may include source material gas and oxidizing gas.

In the film forming method in accordance with an aspect of the invention, the process gas generation section may include a plurality of gas chamber sections in which adjacent ones of the gas chamber sections are connected through a plurality of through-flow pipes, and the source material gas is mixed in repeated compressions and collisions while passing through the gas chamber sections and the through-flow pipes.

In the film forming method in accordance with an aspect of the invention, the film may be a ceramics film.

In the film forming method in accordance with an aspect of the invention, the ceramics film may include at least one kind selected from zinc oxide, magnesium oxide, yttrium oxide, a compound material of boron nitride and silicon nitride, and a compound material of boron oxinitride and silicon oxinitride.

### BRIEF DESCRIPTION OF THE DRAWINGS

FIG. 1 is a schematic diagram showing a film forming apparatus in accordance with an embodiment of the invention.

FIG. 2 is a schematic cross-sectional view of a process gas generation section in accordance with the present embodiment.

FIG. 3 is a perspective view schematically showing a main component of the process gas generation section shown in FIG. 2.

FIG. 4 is a perspective view schematically showing a main component of the process gas generation section shown in FIG. 2 in accordance with a modified example.

FIG. 5 is a schematic cross-sectional view of a film forming section in accordance with the present embodiment.

FIG. 6 is a schematic cross-sectional view of a film forming section in accordance with a modified example of the present embodiment.

FIG. 7 is a cross-sectional view schematically showing a tubular body (glass tube for lamp) in accordance with an embodiment of the invention.

FIG. 8 is a cross-sectional view schematically showing a state in which a ceramics film is formed on an inner wall of a tubular body in accordance with an embodiment of the invention.

FIG. 9 is a schematic perspective view of a lamp formed by the film forming method in accordance with an embodiment of the invention.

FIG. 10A is a graph showing the light transmittivity of a quartz substrate in accordance with an embodiment example, and FIG. 10B is a graph showing the light transmittivity of a sample in accordance with an embodiment example.

FIG. 11 is a graph showing XRD characteristics of a film in accordance with an embodiment example.

### DESCRIPTION OF EXEMPLARY EMBODIMENTS

Preferred embodiments of the invention are described below with reference to the accompanying drawings.

1. Film Forming Apparatus

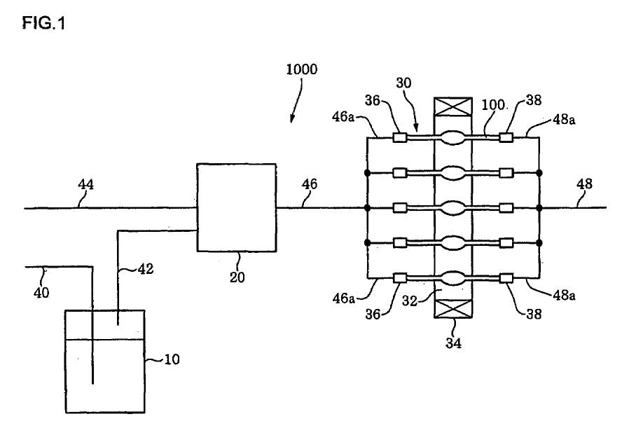

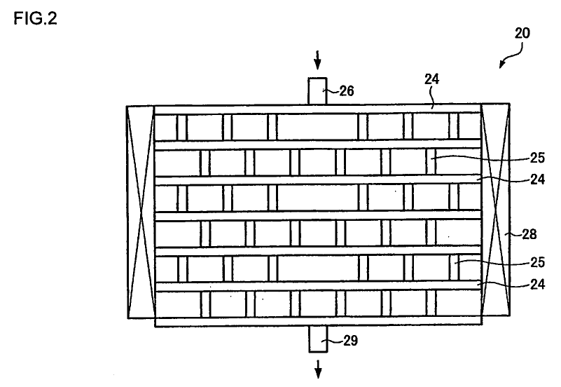

First, an example of a film forming apparatus for tubular bodies in accordance with an embodiment of the invention is described with reference to FIG. 1 and FIG. 2. FIG. 1 is a schematic diagram of a film forming apparatus 1000 in accordance with an embodiment of the invention, and FIG. 2 is a schematic cross-sectional view of a process gas generation section.

The film forming apparatus 1000 in accordance with the present embodiment is a film forming apparatus that forms a film on an inner wall of each tubular body 100 by a CVD method. The film forming apparatus 1000 includes a source material storage section 10, a process gas generation section 20 that forms process gas containing source materials supplied from the source material storage section 10, a film forming section 30 that forms a film on an inner wall of each of the tubular bodies 100, a process gas supply tube 46, and a process gas discharge pipe 48. The process gas supply tube 46 is connected to the tubular bodies 100 and supplies the process gas from the process gas generation section 20 to the tubular bodies 100. The process gas discharge pipe is connected to the tubular bodies 100 and discharges the process gas that has passed through the tubular bodies 100.

In accordance with present embodiment, a glass tube for lamp is used as the tubular body 100. The glass tube for lamp shall be described in detail below. Also, in accordance with the present embodiment, an example of forming a ceramics film on the inner wall of the tubular body 100.

The source material storage section 10 stores various kinds of source materials depending on the film to be formed. For example, when a ceramics film is to be formed by MOCVD, the source material storage section 10 stores an organometallic compound solution as a precursor material for the ceramics film.

The source material storage section 10 is connected to a carrier gas supply pipe 40 for supplying carrier gas, such as, nitrogen, argon and the like. The source material storage section 10 and the process gas generation section 20 are connected by a source material supply pipe 42 that supplies source materials to the process gas generation section 20. Also, an oxidizing gas supply pipe 44 for supplying oxidizing gas, such as, for example, oxygen, ozone and the like is connected to the process gas generation section 20. The oxidizing gas supply pipe 44 is connected to the process gas generation section 20 in the illustrated example, but may be connected to the process gas supply pipe 46.

Process gas formed in the process gas generation section 20 is supplied to the film forming section 30 through the process gas supply pipe 46. In accordance with the present embodiment, the process gas supply pipe 46 has a plurality of supply branch pipes 46a on its downstream side.

The film forming section 30 includes a retaining section 32 that holds a plurality of tubular bodies 100, and a heating section 34 that heats the tubular bodies 100. The retaining section 32 may have any structure without any particular limitation as long as it can hold the plural tubular bodies 100. In the case of the illustrated example, the retaining section 32 is sealed so that the plurality of tubular bodies 100 can be heated by heat from the heating section 34, and may include heating medium that is capable of thermal conduction inside the retaining section. Alternatively, the retaining section 32 may be formed from metal having high thermal conductivity.

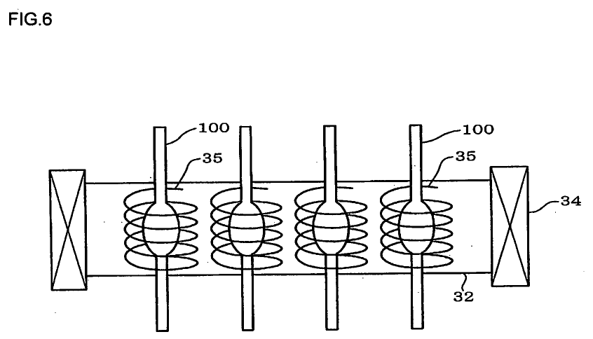

It is noted that, in the example shown in FIG. 1, the heating section 34 is disposed outside the retaining section 32. However, for example, the heating section 34 may be disposed inside the retaining section 32, as shown in FIG. 5. In this case, the heating section 34 is capable of heating any desired regions of the tubular bodies 100. For example, the heating section 34 may mainly heat only a region where the film is formed in the tubular body 100.

Also, as shown in FIG. 6, for example, an electromagnetic induction coil 35 may be wound around a desired region of each of the tubular bodies 100, and a film may be formed on the inner wall of the tubular body 100 in the desired region by an electron cyclotron resonance (ECR) plasma CVD method.

The process gas discharge pipe 48 includes a plurality of discharge branch pipes 48a on its upstream side. The multiple tubular bodies 100 are connected to the supply branch pipes 46a by connectors 36, respectively. Similarly, the multiple tubular bodies 100 are connected to the discharge branch pipes 48a by connectors 38, respectively.

In accordance with the present embodiment, the process gas generation section 20 shown in FIG. 2 can be used.

The process gas generation section 20 includes a plurality of gas chamber sections 24, a plurality of through-flow pipes 25, an inlet section 26 and a heating section 28.

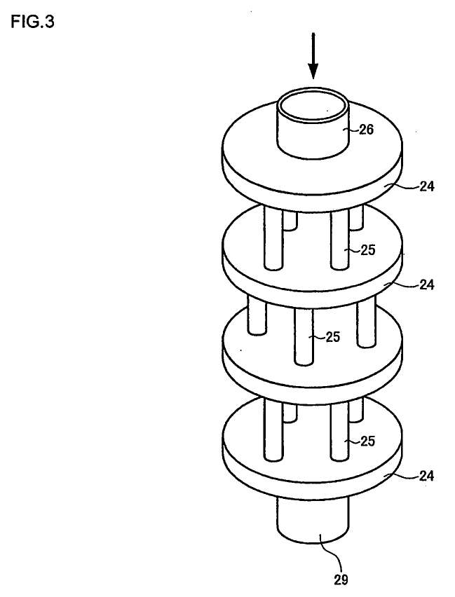

In the example shown in FIG. 2, the gas chamber sections 24 are formed in seven stages. However, the number of stages may be increased or decreased depending on necessity without any particular limitation. The plural through-flow pipes 25 connect the gas chamber sections 24 to one another. The number of through-flow pipes 25 disposed in each stage may be increased or decreased depending on necessity without any particular limitation. As shown in FIG. 3, upper and lower ones of the through-flow pipes 25 adjacent to each of the gas chamber sections 24 may not overlap each other in a plan view. Also, upper and lower ones of the through-flow pipes 25 adjacent to each of the gas chamber sections 24 may be displaced with respect to one another in a plan view. In the illustrated example, the upper set and the lower set of the through-flow pipes 25 are displaced through 45 degrees with respect to each other about the center of the gas chamber sections 24 in a plan view. It is noted that FIG. 3 is a perspective view schematically showing the main portion of the process gas generation section 20, in which the number and the size of components and the like are simplified for the sake of convenience. The gas chamber section 24 may be a flat columnar tube, for example, as shown in the figure. Each of the through-flow pipes 25 may be a long and narrow columnar tube, for example, as shown in the figure. The diameter of the gas chamber section 24 in a plan view is greater than the diameter of the through-flow pipe 25 in a plan view, as shown in the figure. It is noted that the shape and the size of the gas chamber section 24 and the through-flow pipe 25 are not limited to those of the example shown in the figure, and may be changed depending on necessity.

Source material and gas necessary for process gas such as oxygen gas are introduced in the inlet section 26. The inlet section 26 may be a columnar tube, for example, as shown in the figure. The heating section 28 can heat the plural gas chamber sections 24 and the plural through-flow pipes 25.

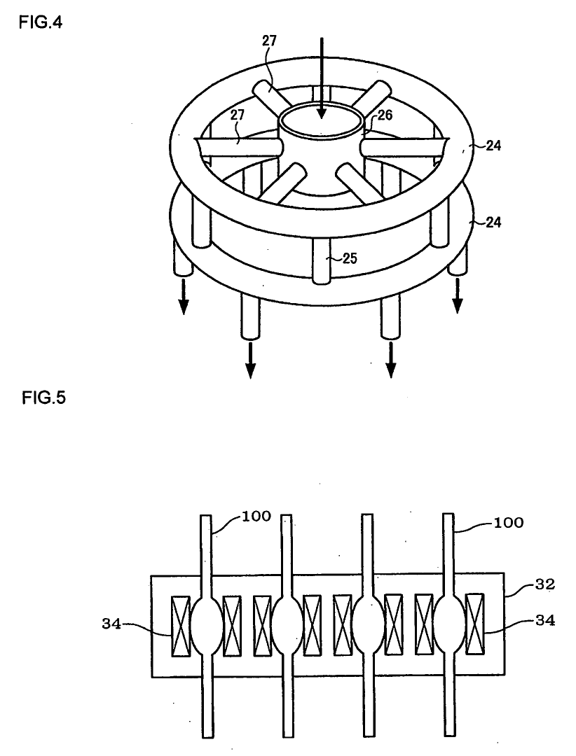

The gas chamber sections 24 and the through-flow pipes 25 may have configuration and arrangement, for example, as shown in FIG. 4. FIG. 4 is a perspective view schematically showing a modified example of the main portion of the process gas generation section 20, in which the number and size of the components are simplified for the sake of convenience. The gas chamber section 24 may be a circular tube, for example, as shown in the figure. The outer diameter of the gas chamber section 24 in a plan view is greater than the diameter of the through-flow pipe 25 in a plan view, as shown in the figure. In the illustrated example, upper and lower sets of the plural through-flow pipes 25 with respect to each of the gas chamber sections 24 are displaced through 45 degrees with respect to each other about the center of the gas chamber sections 24 in a plan view. The gas chamber section 24 in the uppermost stage is connected with the inlet section 26 through a plurality of (six in the example shown in the figure) connecting tubes 27. The inlet section 26 may be a columnar tube closed at its bottom, as shown in the figure, for example. The connecting tubes 27 are radially arranged around the inlet section 26 in a plan. view. It is noted that this modified example is only an example, and the invention is not limited to this modified example.

Source material gas and oxidizing gas are supplied from the process gas generation section 20 to the inlet section 26. The source material gas is supplied from the source material storage section 10 through the source material supply pipe 42 by carrier gas supplied from the carrier gas supply pipe 40. The oxidizing gas is supplied through the oxidizing gas supply pipe 44. The gas inside the inlet section 26 is supplied to the gas chamber section 24 disposed at the topmost stage. In this instance, the gas discharged from the inlet section 26 collides against the bottom surface of the gas chamber section 24 and is diffused. Then the gas is supplied through the plural through-flow pipes 25 connected to the gas chamber section 24 at the topmost stage to the gas chamber section 24 disposed in the next stage while being compressed. In this instance, the gas discharged from the plural through-flow pipes 25 also collide against the bottom surface of the gas chamber section 24 and is diffused. In this manner, the gas introduced into the inlet section 26 can flow from the gas chamber section 24 at the topmost stage to the gas chamber section 24 at the lowermost stage while repeatedly colliding against the bottom surface of each of the gas chamber sections 24 and compressed by the through-flow pipes 25.

The gas chamber sections 24 and the through-flow pipes 25 are heated by the heating section 28, such that the gas flowing inside is also heated. The gas that has flowed from the gas chamber section 24 at the topmost stage to the gas chamber section 24 at the lowermost stage is supplied to the process gas supply pipe 46 as an active gas having oxidizing and reactive characteristics.

The film forming apparatus in accordance with the present embodiment has the following characteristics.

The process gas to be used for forming a film is directly supplied from the process gas generation section 20 to the tubular bodies 100 to be processed, and a film is directly formed on the inner wall of each of the tubular bodies 100 by a CVD method. The tubular body 100 has a smaller volume compared to that of a processing chamber of an ordinary CVD apparatus, and lowering of the process gas temperature due to adiabatic expansion can be made substantially small, such that the temperature control becomes easier and an excellent film, such as, a ceramics film can be formed in a state with smaller energy required for heating.

At the film forming section 30, only portions necessary for forming films in the tubular bodies 100 may be heated, or electromagnetic conduction coils may be wound at the portions, whereby a film can be formed partially on the inner wall of each of the tubular bodies 100, and therefore the degree of freedom in design is increased.

A plurality of tubular bodies 100 to be processed are disposed in the film forming section 30, and the process gas is supplied through the tubular bodies 100, whereby the plurality of tubular bodies 100 can be simultaneously processed.

Furthermore, when an apparatus having the plurality of gas chamber sections 24 and through-flow pipes 25 described above as the process gas generation section 20, process gas with active reactivity can be obtained, such that a good quality film, for example, a good quality ceramics film can be obtained at lower temperatures, compared to the case where an ordinary CVD method is used.

The tubular body 100 of the present embodiment is not limited to glass tubes for lamp, and is also applicable to any tubular objects to be processed.

2. Film Forming Method The film forming apparatus 1000 is used to form a film, for example, a ceramics film on an inner wall of each tubular body 100 in the following manner.

(A) A plurality of tubular bodies 100 are set at the retaining section 32 of the film forming section 30. Then, each of the tubular bodies 100 is connected to the supply branch pipe 46a of the process gas supply pipe 46 through the connector 36, and each of the tubular bodies 100 is connected to the discharge branch pipe 48a by the connector 38. By connecting each of the tubular bodies 100 to the supply branch pipe 46a and the discharge branch pipe 48a, the process gas supplied from the process gas generation section 20 passes through each of the tubular bodies 100 to be processed.

(B) The source material, such as, organometallic compound is supplied by the carrier gas from the source material storage section 10 through the source material supply pipe 42 to the process gas generation section 20, and the oxidizing gas is also supplied through the oxidizing gas supply pipe 44 to the process gas generation section 20. Process gas containing the source material gas and oxidizing gas is formed by the process gas generation section 20. By using the process gas generation section 20 described above and shown in FIG. 2, the process gas is provided with active oxidizing property and reactivity.

(C) The process gas is supplied only inside the tubular bodies 100 to be processed from the process gas generation section 20 through the process gas supply pipe 46 and the supply branch pipes 46a. In this instance, compared to the case of an ordinary CVD apparatus where process gas is supplied inside the apparatus chamber that has a greater volume than that of the object to be processed, the process gas in accordance with the present embodiment is supplied inside the tubular bodies 100 without any waste, and a reduction in the process gas temperature due to adiabatic expansion can be made considerably smaller.

(D) Within the tubular bodies 100, a ceramics film is formed on the inner wall of each of the tubular bodies 100 by a CVD method using the process gas. In this case, each of the tubular bodies 100 also functions as a chamber for forming a film by a CVD method, such that the process gas can be used for film formation without any waste. Also, as described above, compared to the process chamber of an ordinary CVD apparatus, the tubular body 100 has a smaller volume, and can make the reduction in the process gas temperature due to adiabatic expansion considerably smaller, such that controlling of the temperature becomes easier, and a film, such as, a ceramics film can be formed in a state with smaller energy for heating. The CVD method may be, for example, a thermal CVD method, a plasma CVD method (including a high density plasma CVD method).

The retaining section 32 is heated by the heating section 34, and the tubular bodies 100 are also heated by the heating section 34. In accordance with the present embodiment, the process gas (reactive gas) flows inside the tubular bodies 100 that are heated, and a ceramics film is formed in a manner to cover the inner surface of each of the tubular bodies 100 by a thermal CVD method.

(E) The process gas that has passed through each of the tubular bodies 100 is discharged through the discharge branch pipe 48a and the process gas discharge pipe 48.

In this manner, the tubular body 100 having a film (a ceramics film) formed on its inner wall can be obtained.

The film forming method in accordance with the present embodiment also provides characteristics similar to those of the film forming apparatus described above.

3. Application Example

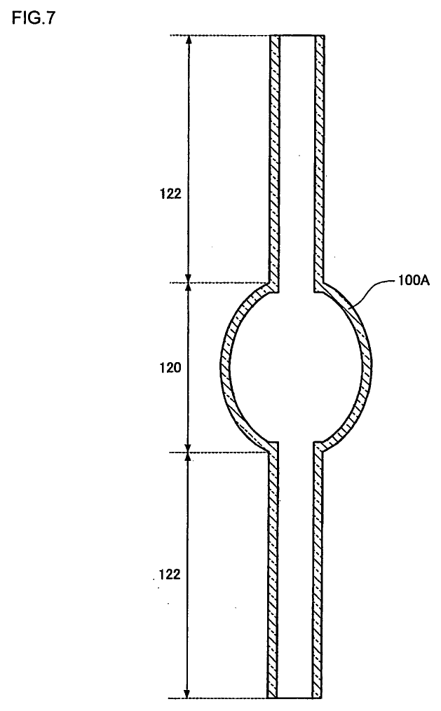

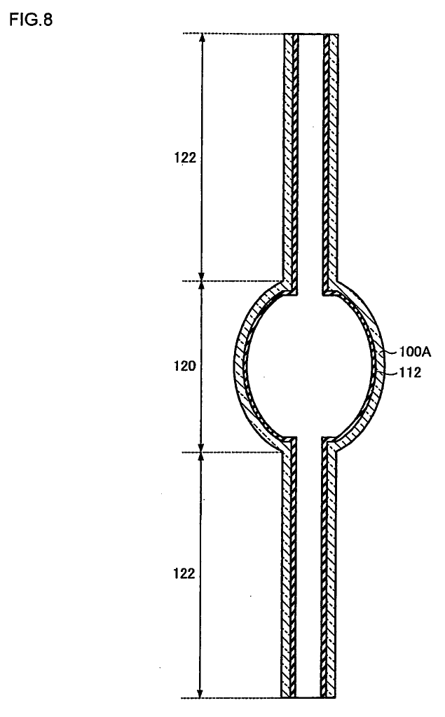

An example in which the tubular body 100 in accordance with the present embodiment is applied to a glass tube for lamp is described below. FIG. 7 is a schematic cross-sectional view of a glass tube for lamp 100A, and FIG. 8 is a cross-sectional view of the glass tube 100A in a state in which a ceramics film 112 is formed on its inner wall.

The glass tube for lamp 100A is in a tubular configuration that opens at both ends thereof. The glass tube 100A in its central area (hereafter also referred to as a “first area”) 120 has a diameter greater than a diameter of the glass tube 100A in other areas (hereafter also referred to as “second areas”) 122. In other words, the first area 120 is generally located in the center of the glass tube 100A along its longitudinal direction. The second areas 122 are located on both sides of the first area 120 in the longitudinal direction of the glass tube 100A. The glass tube 100A in the first area 120 may be, for example, in a spherical shape, an elliptic spherical shape, or the like. The second areas 122 of the glass tube 100A are formed in a pair on both sides of the first area 120 of the glass tube 100A, and continuous from the first area 120 of the glass tube 100A. The glass tube 100A in each of the second areas 122 may be formed, for example, in a circular column tube, a rectangular column tube or the like. The glass tube 100A may be formed from, for example, quartz glass.

The ceramics film 112 covers at least a portion of the inner surface of the glass tube 100A in the first area 120. For example, as illustrated, the ceramics film 112 may entirely cover the inner surface of the glass tube 100A in the first area 120 and the second areas 122. The film thickness of the ceramics film 112 in the first area 120 and the second areas 122 may be, for example, as illustrated, smaller than the film thickness of the glass tube 100A in the first area 120 and the second areas 122. Although not shown, the ceramics film may be mainly formed only in the first region 120.

The ceramics film 112 is formed from a material selected from, for example, zinc oxide (ZnO), magnesium oxide (MgO), yttrium oxide (Y₂O₃), a compound material of boron nitride and silicon nitride (hereafter also referred to as “BN-SiN”), and a compound material of boron oxinitride and silicon oxinitride (hereafter also referred to as “BON—SiON”). For example, the devitrification temperature of ZnO, MgO, Y₂O₃, BN—SiN and BON—SiON is 1500° C. or higher. BN—SiN may be expressed, for example, by a general formula, (BN)ₓ (Si₃N₄)₁₋ₓ, where 0<x<1. SiON—BON may be expressed, for example, by a general formula, (SiO_{y}N_{1-y})ₓ (BO_{z}N_{1-z})₁₋ₓ, where 0<x<1, 0<y<1, and 0<z<1.

The ceramics film 112 may have a single-layer structure composed of one of BN—SiN, BON—SiON, ZnO, MgO and Y₂O₃. Also, the ceramics film 112 may have a multilayer structure of laminated multiple layers composed of materials including BN—SiN, BON—SiON, ZnO, MgO and Y₂O₃.

When a ceramics film composed of BON—SiOn is formed, for example, tris (trimethylsiloxy) borate may be used as the source material gas for the ceramics film. When a ceramics film composed of ZnO is formed, for example, bis (6-ethyl-2, 2-dimethyl-3, 5-decanodionate) zinc may be used as the source material gas for the ceramics film. When a ceramics film composed of MgO is formed, for example, bis (6-ethyl-2, 2-dimethyl-3, 5-decanodionate) magnesium (Mg (EDMDD)₂) may be used as the source material gas for the ceramics film. When a ceramics film composed of Y₂O₃ is formed, for example, tris (sec-butylcyclopentadienyl) yttrium (Y (sBuCp)₃) may be used as the source material gas for the ceramics film.

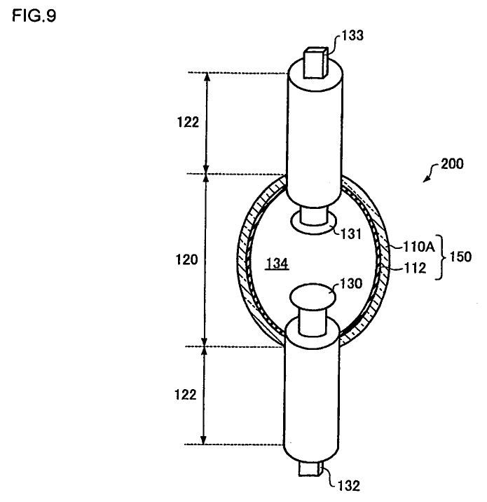

FIG. 9 is a perspective view schematically showing a lamp 200 formed by the film forming apparatus in accordance with an embodiment of the invention, and also shows a cross section in part thereof. The lamp 200 may be, for example, a high-pressure mercury vapor lamp. The lamp 200 includes a glass tube for the lamp 150, a first electrode 130, a second electrode 131, a first terminal 132, a second terminal 133, and an internal space 134. The internal space 134 is present inside the ceramics film 112 in a first area 120. For example, mercury, rare gas, and halogen are enclosed in the internal space 134. The first electrode 130 and the second electrode 131 are disposed inside the internal space 134. The first electrode 130 and the second electrode 131 are electrodes for discharging. The first electrode 130 and the second electrode 131 may be formed from, for example, tungsten. The first electrode 130 is electrically connected to the first terminal 132 through a metal foil (not shown) sealed inside the ceramics film 112 in the second region 122. Similarly, the second electrode 131 is electrically connected to the second terminal 133. The first terminal 132 and the second terminal 133 are power supply terminals, and are lead out from both ends of the glass tube for lamp 150.

The lamp 200 is applicable, for example, to devices that use light emitted by plasma radiation within the glass tube for lamp 150 (for example, projector lamps, fluorescent tubes and the like). Also, the lamp 200 may be, for example, a metal halide lamp or a xenon lamp, without being limited to a high-pressure mercury lamp.

When the film forming apparatus and the film forming method in accordance with the present embodiment are applied to, for example, the lamp 200 shown in FIG. 9, the following characteristics are obtained.

The entire inner surface of the glass tube 100A in the first area 120 or at least the light emitting section thereof is coated with the ceramics film 112. By this, adhesion of impurities to the inner surface of the glass tube 100A can be prevented, and the devitrification temperature of the glass tube 100A can be prevented from lowering. Accordingly, the service life of the lamp 200 can be extended. It is noted that, by covering at least a portion of the inner surface of the glass tube 100A in the first area 120 with the ceramics film 112, the service life of the lamp 200 can be extended.

Further, the inner surface of the glass tube 100A can be covered in a specified area by the ceramics film 112 formed from a thin film. For example, the film thickness of the ceramics film 112 in at least the first area 120 can be made smaller than the film thickness of the glass tube 100A in the first area 120, or almost no ceramics film may be formed. Therefore, for example, when the light transmittivity of the ceramics film 112 is lower than that of the glass tube 100A in the same film thickness, the light transmittivity of the glass tube for lamp 150 in the first area 120 can be prevented from lowering, while the service life of the lamp 200 can be extended, as described above.

### 4. EMBODIMENT EXAMPLE

Embodiment examples of the invention are described below, but the invention is not limited to the embodiment examples.

### 4.1. Embodiment Example 1

As reactive chemical species as the source material, tris (sec-butylcyclopentadienyl) yttrium (Y (sBuCp)₃) was used. The source material was supplied to the process gas generation section shown in FIG. 2 together with nitrogen gas and oxygen gas, whereby process gas was obtained. The process gas was supplied to the film forming section (reaction chamber), and a film was formed on the inner wall of the glass tube for lamp.

The flow quantity of the source material gas in the reaction chamber was 0.3 ccm, the flow quantity of nitrogen gas was 1.5 slm, and the flow quantity of oxygen gas was 0.5 slm. As the conditions set in the reaction chamber, the pressure was 400 Pa, the temperature was 600° C., and the processing time was 30 minutes. As the conditions relating to the process gas generation section, the piping temperature for the source material (i.e., the temperature of the source material) was 220° C., and the temperature of oxygen gas was 400° C. As the glass tube for lamp, a quartz glass tube for projector lamp was used. The glass tube was 300 mm in length, and the light emitting section (the first area 120 in FIG. 8) was 10 mm in length. The outer diameter of the glass tube and the light emitting section was 5 mm and 7 mm, respectively, and the inner diameter of the glass tube and the light emitting section was 1 mm and 3 mm, respectively.

Interference colors were observed on the inner wall of the glass tube after film formation, and it was confirmed that a transparent film having a generally uniform film thickness was formed.

### 4.2. Embodiment Example 2

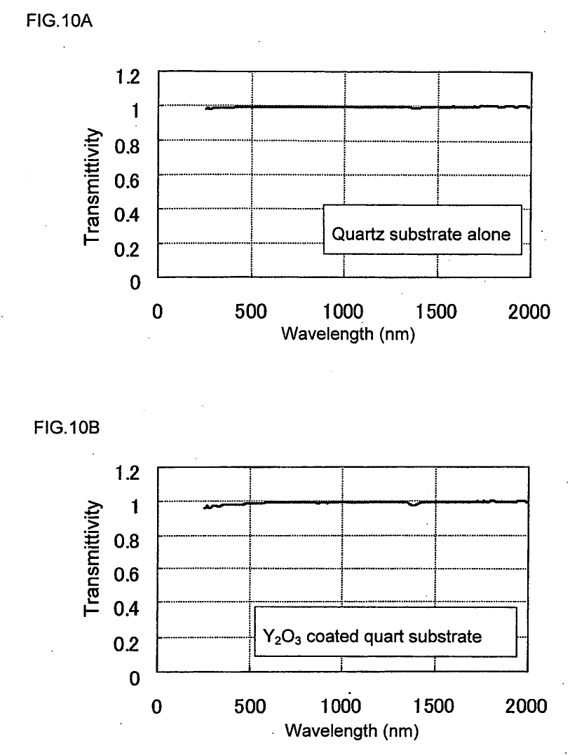

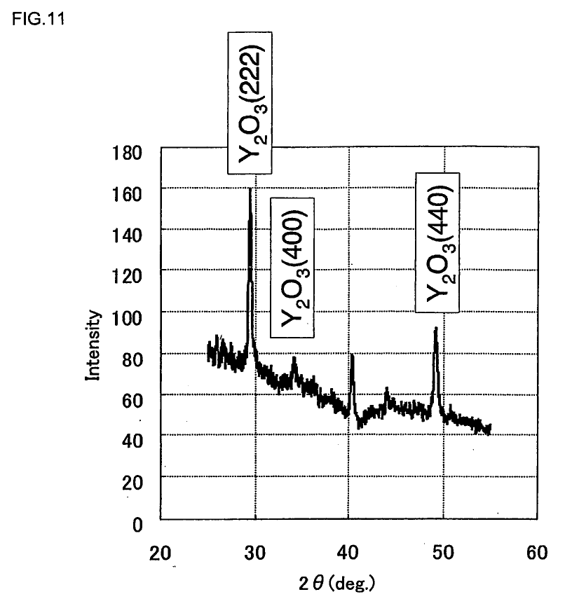

A film was formed on a surface of a plate-like quartz substrate under conditions similar to those used in Embodiment Example 1 described above. Light transmittivity and XRD characteristics of the obtained films were measured. The results are shown in FIGS. 10A and 10B and FIG. 11. FIG. 10A shows the light transmittivity of the single quartz substrate, and FIG. 10B shows the light transmittivity of the sample in which a film was formed on a quartz substrate.

It is observed from comparison of FIG. 10A and FIG. 10B that there is hardly any difference in light transmittivity between the sample with the film formed thereon and the substrate without a film formed thereon. Accordingly, it was confirmed that the film obtained in the embodiment example had high light transmittivity and was transparent. Also, it was confirmed that the film obtained in the embodiment example was a crystalline film of yttrium oxide.

In view of the above, according to the embodiment example of the invention, it was confirmed that a film having high crystallinity was formed on the inner wall of the tubular body.

The embodiments of the invention are described above in detail. However, it is readily understood by a person having ordinary skill in the art that many modifications can be made without departing in substance from the novel matter and effects of the invention. Accordingly, all of these modified examples are deemed included in the scope of the invention.

What is claimed is:

1. A film forming apparatus that forms a film on an inner wall of a tubular body by a chemical vapor deposition method, the film forming apparatus comprising:
a source material storage section;
a process gas generation section that forms process gas containing source material supplied from the source material storage section;
a film forming section that forms a film on an inner wall of the tubular body;
a process gas supply tube that connects to the tubular body and supplies the process gas from the process gas generation section to the tubular body; and
a process gas discharge tube that connects to the tubular body and discharges the process gas that has passed through the tubular body, wherein the film forming section includes a retaining section that holds the tubular body.

2. A film forming apparatus according to claim 1, wherein the film forming section includes a heating section for heating the tubular body.

3. A film forming apparatus according to claim 1, wherein the process gas generation section includes a plurality of gas chamber sections disposed at intervals, a plurality of through-flow pipes that connect the plurality of gas chamber sections, and a heating section that heats the plurality of gas chamber sections and the plurality of through-flow pipes.

4. A film forming apparatus according to claim 3, wherein adjacent upper and lower sets of the plurality of through-flow pipes with respect to each of the gas chambers do not overlap each other in a plan view.

5. A film forming apparatus according to claim 1, wherein the tubular body is a glass tube for lamp.

6. A film forming apparatus according to claim 1, wherein the process gas supply tube includes a plurality of supply branch pipes, the process gas discharge pipe includes a plurality of discharge branch pipes, and the retaining section connect the supply branch pipes and the discharge branch pipes, respectively.

7. A film forming method that forms a film on an inner wall of a tubular body by a chemical vapor deposition method, the method comprising the steps of:
setting a tubular body at a retaining section of a film forming apparatus, and connecting the tubular body to a process gas supply pipe and to a process gas discharge pipe;
supplying at least source material gas to a process gas generation section;
supplying the process gas from the process gas generation section into the tubular body through the process gas supply pipe;
forming a film on an inner wall of the tubular body by a chemical vapor deposition method using the process gas; and
discharging the process gas that has passed through the tubular body from the process gas discharge pipe.

8. A film forming method according to claim 7, further comprising heating the tubular body by a heating section, and maintaining the tubular body at a film forming temperature.

9. A film forming method according to claim 7, wherein the process gas includes source material gas and oxidizing gas.

10. A film forming method according to claim 7, wherein the process gas generation section includes a plurality of gas chamber sections in which adjacent ones of the gas chamber sections are connected through a plurality of through-flow pipes, and the source material gas is mixed in repeated compressions and collisions while passing through the gas chamber sections and the through-flow pipes.

11. A film forming method according to claim 7, wherein the film is a ceramics film.

12. A film forming method according to claim 11, wherein the ceramics film includes at least one kind selected from zinc oxide, magnesium oxide, yttrium oxide, a compound material of boron nitride and silicon nitride, and a compound material of boron oxinitride and silicon oxinitride.
